(19) United States
(12) Patent Application Publication
(10) Pub. No.: US 2025/0361441 A1
(43) Pub. Date: Nov. 27, 2025

(54) ETCHING COMPOSITION, ETCHING METHOD, METHOD FOR MANUFACTURING SEMICONDUCTOR DEVICE, AND METHOD FOR MANUFACTURING GATE-ALL-AROUND-TYPE TRANSISTOR

(71) Applicant: MITSUBISHI CHEMICAL CORPORATION, Tokyo (JP)

(72) Inventors: Hiroyuki SHIRAE, Tokyo (JP); Tetsuo KASAI, Tokyo (JP); Haru SENDO, Tokyo (JP)

(73) Assignee: MITSUBISHI CHEMICAL CORPORATION, Tokyo (JP)

(21) Appl. No.: 19/295,266

(22) Filed: Aug. 8, 2025

Related U.S. Application Data
(63) Continuation of application No. PCT/JP2024/004306, filed on Feb. 8, 2024.

(30) Foreign Application Priority Data
Feb. 10, 2023 (JP) 2023-019284
May 23, 2023 (JP) 2023-084973

(51) Int. Cl. C09K 13/02; C30B 29/06; C30B 33/10; H01L 21/306; H10D 30/01

(52) U.S. Cl. CPC C09K 13/02; C30B 29/06; C30B 33/10; H01L 21/30604; H10D 30/0191

(57) ABSTRACT

An etching composition including an alkaline compound (A) and a thiol compound (B), wherein the etching composition dissolves silicon.

### CROSS-REFERENCE TO RELATED APPLICATIONS

The present application is a continuation of International Patent Application PCT/JP2024/004306, filed Feb. 8, 2024, which is based on and claims the benefit of priority to Japanese Patent Application No. 2023-019284 filed on Feb. 10, 2023 and Japanese Patent Application No. 2023-084973 filed on May 23, 2023. The entire contents of these applications are incorporated herein by reference.

### TECHNICAL FIELD

The present invention relates to etching compositions, an etching method, a method for manufacturing a semiconductor device, and a method for manufacturing a gate-all-around transistor.

### BACKGROUND ART

Integrated circuits are increasingly scaled down according to Moore's law.

In recent years, studies have been conducted to improve performance and advance further scaling-down and integration not only by reducing the size of the conventional planar transistors but also by changing the structure from flat to three-dimensional; examples of such modifications include fin transistors (fin FET) and gate-all-around transistors (GAA FET).

In fin FETs, by forming fins on a silicon substrate in a vertical direction to form a multi-gate device, the number of transistors per unit area can be increased and the off-state leakage current can be suppressed. This improves the effect of the on-state current, thereby achieving low power consumption and low heat generation. In addition, it exhibits excellent performance in ON/OFF control at low voltages.

In order to further improve the performance of fin FETs, it would require an alteration, such as an increase in an aspect ratio of the fins. However, when the aspect ratio is excessively high, problems arise, such as a collapse of the fins in a cleaning process or a drying process used for the formation of the fins.

In GAA FETs, the performance of the transistors per unit area is improved by covering a nanosheet or a nanowire, which serves as a channel, with a gate electrode, thereby increasing an area of contact between the channel and the gate electrode.

The formation of GAA FETs requires an etching liquid for selectively etching silicon or silicon germanium from a structure in which silicon and silicon germanium are alternately layered.

As such an etching liquid, Patent Literature 1 discloses an etching liquid that contains an organic alkaline compound such as a quaternary ammonium hydroxide and the like and water, and has a dissolved oxygen concentration equal to or less than a specified value.

### CITATION LIST

### Patent Literature

Patent Literature 1: WO 2022/172907 A

### SUMMARY OF INVENTION

### Technical Problem

As in Patent Literature 1, an etching liquid containing an organic alkaline compound and not containing a thiol compound cannot suppress the dissolution of silicon germanium, and is inferior in ability to selectively dissolve silicon over silicon germanium.

In particular, in recent years, there has been a strong demand for miniaturization of FETs, and an etching liquid having the ability to selectively etch silicon or silicon germanium in narrow gaps of several tens of nanometers. In such narrow gaps, the etching rate is extremely slower than when etching a smooth substrate, and problems different from those in the case of etching a smooth substrate occur. For this reason, an etching liquid suitable for etching such narrow gaps is needed.

However, the etching liquid disclosed in Patent Literature 1 does not have the ability required for etching such narrow gaps.

An object of the present invention is to provide etching compositions that promote dissolution of silicon while inhibiting dissolution of silicon germanium and, therefore, have excellent ability to selectively dissolve silicon over silicon germanium.

Another object of the present invention is to provide an etching method, a method for manufacturing a semiconductor device, and a method for manufacturing a gate-all-around transistor; these methods use any of the etching compositions.

### Solution to Problem

The inventors of the present invention found that an etching composition containing an alkaline compound and a thiol compound promotes dissolution of silicon while inhibiting dissolution of silicon germanium and, therefore, has excellent ability to selectively dissolve silicon over silicon germanium.

The features of the present invention are as follows.
[1] An etching composition comprising an alkaline compound (A) and a thiol compound (B), wherein the etching composition dissolves silicon.
[2] The etching composition according to [1], wherein the silicon is single-crystal silicon.
[3] The etching composition according to [1] or [2], wherein the alkaline compound (A) comprises a quaternary ammonium compound (A1).
[4] The etching composition according to [3], wherein the quaternary ammonium compound (A1) comprises a quaternary alkylammonium compound having a total of 8 or more carbon atoms in the alkyl groups.
[5] The etching composition according to [3] or [4], wherein the quaternary ammonium compound (A1) comprises a semiclathrate hydrate-forming compound.
[6] The etching composition according to [1] or [2], wherein the alkaline compound (A) comprises an inorganic alkaline compound (A2).
[7] The etching composition according to [6], wherein the inorganic alkaline compound (A2) comprises a metal hydroxide.
[8] The etching composition according to [7], wherein the inorganic alkali compound (A2) comprises potassium hydroxide.
[9] The etching composition according to any one of [1] to [8], wherein the thiol compound (B) comprises a compound having a hydrocarbon group and a thiol group.
[10] The etching composition according to any one of [1] to [9], wherein the thiol compound (B) comprises at least one compound selected from the group consisting of thioglycerol, thioglycolic acid, ethanolamine thioglycolate, 8-mercaptooctanoic acid, 1-octanethiol, 1-undecanethiol, 1-dodecanethiol, 11-mercapto-1-undecanol, 11-mercaptoundecanoic acid, 16-mercaptohexadecanoic acid, 4,4′-dithiodibutyric acid, bis(2-hydroxyethyl) disulfide, and didodecane disulfide.
[11] The etching composition according to any one of [1] to [10], further comprising water.
[12] The etching composition according to [11], wherein a content of water is 60% by mass or more based on 100% by mass of the composition.
[13] The etching composition according to any one of [1] to [12], wherein a content of the alkaline compound (A) is 0.1% by mass or more and 39.99% by mass or less based on 100% by mass of the composition.
[14] The etching composition according to any one of [1] to [13], wherein a content of the thiol compound (B) is 0.01% by mass or more and 5% by mass or less based on 100% by mass of the composition.
[15] The etching composition according to any one of [1] to [14], wherein a ratio of the mass of the thiol compound (B) to the mass of the alkaline compound (A) is 0.001 to 2.
[16] The etching composition according to any one of [1] to [15], wherein a content of a glycerol compound is 5% by mass or less based on 100% by mass of the composition.
[17] The etching composition according to any one of [1] to [16], wherein the composition has a ratio ER_{Si}/ER_{SiGe} of 3 or more, wherein ER_{Si} is an etching rate for single crystal silicon and ER_{SiGe} is an etching rate for silicon germanium in a structure, in which silicon germanium having a film thickness of 10 nm and single crystal silicon having a film thickness of 10 nm are stacked.
[18] An etching method comprising etching silicon by using the etching composition according to any one of [1] to [17].
[19] The etching method according to [18], wherein the silicon is single crystal silicon.
[20] A method for manufacturing a semiconductor device comprising a step of etching silicon by using the etching composition according to any one of [1] to [17].
[21] The method for manufacturing a semiconductor device according to [20], wherein the silicon is single crystal silicon.
[22] A method for manufacturing a gate-all-around transistor comprising a step of etching silicon by using the etching composition according to any one of [1] to [17].
[23] The method for manufacturing a gate-all-around transistor according to [22], wherein the silicon is single crystal silicon.

### Advantageous Effects of Invention

The etching composition of the present invention promotes dissolution of silicon while inhibiting dissolution of silicon germanium and, therefore, has excellent ability to selectively dissolve silicon over silicon germanium. Therefore, the etching composition of the present invention can be suitably used as an etching liquid that selectively dissolves silicon relative to silicon germanium.

The etching method of the present invention, the method of the present invention for manufacturing a semiconductor device, and the method of the present invention for manufacturing a gate-all-around transistor use the etching composition of the present invention. Accordingly, in the etching steps, these methods promote dissolution of silicon while inhibiting dissolution of silicon germanium and, therefore, provide excellent ability to selectively dissolve silicon over silicon germanium; consequently, the methods enable high-precision etching to be carried out, thereby enabling high-yield manufacture of desired products.

### DESCRIPTION OF EMBODIMENTS

The present invention will be described in detail below. The present invention is not limited to the embodiments described below and can be practiced with various modifications within the scope of the present invention. In this specification, when numerical ranges are expressed with the term “to”, the preceding and following numerical values or physical property values are inclusive.

### Etching Composition

The etching composition of the present invention (hereinafter, sometimes referred to as the “composition of the present invention”) is an etching composition that dissolves silicon, containing an alkaline compound (A) (hereinafter, sometimes referred to as the “component (A)”) and a thiol compound (B) (hereinafter, sometimes referred to as the “component (B)”).

The composition of the present invention contains an alkaline compound (A) and a thiol compound (B). Consequently, the etching composition can promote dissolution of silicon while inhibiting dissolution of silicon germanium and, therefore, has excellent ability to selectively dissolve silicon over silicon germanium. In particular, it is excellent in ability to selectively dissolve single crystal silicon over silicon germanium.

The etching composition of the present invention preferably further contains water (hereinafter, sometimes referred to as the “component (C)”).

### Component (A)

The component (A) is an alkaline compound.

By containing the component (A), the etching composition of the present invention exhibits the effect of dissolving silicon and silicon germanium, or exhibits excellent ability to selectively dissolve silicon over silicon germanium.

The alkaline compound of the component (A) may be any compound that exhibits alkaline, and examples thereof include primary to tertiary ammonium compounds belonging to organic alkaline compounds, quaternary ammonium compounds (A1), alkoxides, metal amides, metal alkyls, pyridine compounds, heterocyclic amine compounds, primary to quaternary phosphonium compounds, inorganic alkaline compounds (A2), and the like.

These alkaline compounds may be used alone or in combination of two or more.

Among these alkaline compounds, a quaternary ammonium compound (A1) (hereinafter, sometimes referred to as the “component (A1)”) is preferred because it has excellent stability in air and excellent solubility of silicon, and does not contain metals that can become impurities in semiconductor manufacturing, and an inorganic alkaline compound (A2) (hereinafter, sometimes referred to as the “component (A2)”) is preferred because it has excellent stability in air and excellent solubility of silicon.

One or more of the quaternary ammonium compounds (A1) may be used in combination with one or more of the inorganic alkali compounds (A2).

### Quaternary Ammonium Compound (A1)

The component (A1) is a quaternary ammonium compound (A1).

The etching composition of the present invention exhibits the effect of dissolving silicon and silicon germanium by containing a quaternary ammonium compound (A1).

The component (A1) is preferably a quaternary alkyl ammonium compound having a total number of carbon atoms in the alkyl groups of 8 or more, since it has excellent selective solubility of silicon over silicon germanium. This total number of carbon atoms is more preferably 8 to 32, and even more preferably 12 to 24.

The quaternary alkyl ammonium compound as the component (A1) preferably has the same four alkyl groups, since it has germanium. In particular, it is preferable that the component (A1) contains 50% by mass or more of quaternary alkyl ammonium compounds in which the four alkyl groups are the same, more preferably 70% by mass or more, and even more preferably 90% by mass or more, based on 100% by mass of the component (A1). It is most preferable that the component (A1) contains 100% by mass of quaternary alkyl ammonium compounds in which the four alkyl groups are the same.

These quaternary ammonium compounds (A1) may be used alone or in combination of two or more types.

Among these quaternary ammonium compounds (A1), tetraethylammonium hydroxide, tetrapropylammonium hydroxide, tetrabutylammonium hydroxide, tetrahexylammonium hydroxide, tetraoctylammonium hydroxide, benzyltrimethylammonium hydroxide, and tetrabutylammonium bromide are preferable in terms of providing excellent ability to selectively dissolve silicon over silicon germanium; tetraethylammonium hydroxide, tetrapropylammonium hydroxide, tetrabutylammonium hydroxide, and benzyltrimethylammonium hydroxide are more preferable; tetraethylammonium hydroxide, tetrapropylammonium hydroxide, and tetrabutylammonium hydroxide are even more preferable; and tetrabutylammonium hydroxide is most preferable.

Furthermore, the component (A1) is preferably a semiclathrate hydrate-forming compound because it has germanium.

A semiclathrate hydrate-forming compound is a compound that becomes a guest molecule that stabilizes a clathrate hydrate by forming a hydrogen bond network. As the semiclathrate hydrate-forming compound, the compound having a melting point of 5° C. or higher (hereinafter, this melting point may be referred to as the “melting point of the clathrate hydrate”) in a clathrate hydrate having a concentration of 1 mol/L of the component (A1) is preferable, since this compound has excellent reaction controllability of water molecules due to hydration in the temperature range where the etching rate is fast.

Examples of the component (A1) that satisfies the above mentioned preferable conditions include quaternary alkyl ammonium compounds such as tetrabutylammonium hydroxide (melting point of the clathrate hydrate: 26° C.), tetrabutylammonium bromide (melting point of the clathrate hydrate: 15° C.), and the like.

### Inorganic Alkali Compound (A2)

The component (A2) is an inorganic alkali compound (A2). By containing the inorganic alkali compound (A2), the etching composition of the present invention promotes the dissolution of silicon and has excellent selective solubility of silicon over silicon germanium.

Examples of the component (A2) include metal hydroxides of alkali metals or alkaline earth metals, such as sodium hydroxide, potassium hydroxide, calcium hydroxide, and the like.

These components (A2) may be used alone or in combination of two or more.

Among these components (A2), metal hydroxides are preferable because they have excellent silicon solubility; sodium hydroxide, potassium hydroxide, and calcium hydroxide are more preferable; and potassium hydroxide is even more preferable.

### Content of Component (A)

The content of the component (A) in the composition of the present invention is preferably 0.1% by mass or more, more preferably 1% by mass or more, and even more preferably 2.5% by mass or more, based on 100% by mass of the composition of the present invention, from the viewpoint of excellent selective solubility of silicon over silicon germanium.

The content of the component (A) in the composition of the present invention is preferably 39.99% by mass or less, more preferably 35% by mass or less, and even more preferably 30% by mass or less, from the viewpoints of preventing the dissolution of silicon germanium and providing excellent selective solubility of silicon over silicon germanium.

When the composition of the present invention contains the component (A1) as the component (A), the content of the component (A1) is preferably 5% by mass or more, more preferably 10% by mass or more, and even more preferably 15% by mass or more based on 100% by mass of the etching composition of the present invention, from the viewpoints of promoting the dissolution of silicon and providing excellent selective solubility of silicon over silicon germanium.

The content of the component (A1) is preferably 39.99% by mass or less, more preferably 35% by mass or less, and even more preferably 30% by mass or less based on 100% by mass of the etching composition of the present invention, from the viewpoints of preventing the dissolution of silicon germanium and providing excellent selective solubility of silicon over silicon germanium.

When the composition of the present invention contains the component (A2) as the component (A), the content of the component (A2) is preferably 0.5% by mass or more, more preferably 2% by mass or more, and even more preferably 5% by mass or more based on 100% by mass of the composition of the present invention, from the viewpoints of promoting the dissolution of silicon and providing excellent selective solubility of silicon over silicon germanium.

The content of the component (A2) is preferably 39.99% by mass or less, more preferably 35% by mass or less, and even more preferably 30% by mass or less based on 100% by mass of the composition of the present invention, from the viewpoints of preventing the dissolution of silicon germanium and providing excellent selective solubility of silicon over silicon germanium.

### Component (B)

The component (B) is a thiol compound (B).

When the etching composition of the present invention contains a thiol compound (B), the thiol compound (B) is adsorbed to the surface of silicon germanium due to the interaction between the thiol group and germanium, and the effect of protecting silicon germanium is exerted.

The thiol compound (B) of the present invention may be one that decomposes in the composition to generate a thiol compound. Therefore, a compound that decomposes in the composition to generate a thiol compound, such as a disulfide compound, also falls under the component (B) of the present invention. In other words, the etching composition of the present invention may contain a disulfide compound as the component (B).

From the viewpoint of densely covering the surface of silicon germanium and exerting the effect of protecting silicon germanium, the component (B) is preferably a compound having a hydrocarbon group and a thiol group, and more preferably a compound having a hydrophobic hydrocarbon group and a thiol group.

Examples of such thiol compound (B) include thioglycerol, thioglycolic acid, ethanolamine thioglycolate, 8-mercaptooctanoic acid, 1-octanethiol, 1-undecanethiol, 1-dodecanethiol, 11-mercapto-1-undecanol, 11-mercaptoundecanoic acid, 16-mercaptohexadecanoic acid, 4,4′-dithiodibutyric acid, bis(2-hydroxyethyl)disulfide, didodecane disulfide, and the like.

Among these, thioglycerol, thioglycolic acid, ethanolamine thioglycolate, 1-octanethiol, 1-undecanethiol, 1-dodecanethiol, 11-mercapto-1-undecanol, 11-mercaptoundecanoic acid, and 16-mercaptohexadecanoic acid are preferred, and thioglycerol, thioglycolic acid, ethanolamine thioglycolate, 11-mercaptoundecanoic acid, and 16-mercaptohexadecanoic acid are more preferred, from the viewpoints of easy availability, low volatility, odor suppression, and ease of handling. From the viewpoint of forming a self-assembly monolayer (SAM) and being particularly excellent in the effect of protecting silicon germanium, 11-mercaptoundecanoic acid and 16-mercaptohexadecanoic acid are even more preferred as the thiol compound (B).

As the thiol compound (B), one type may be used alone, or two or more types may be used in combination.

The content of the component (B) is preferably 0.01% by mass or more, more preferably 0.05% by mass or more, and even more preferably 0.08% by mass or more based on 100% by mass of the etching composition of the present invention, since it suppresses the dissolution of silicon germanium and has germanium.

The content of the component (B) is preferably 5% by mass or less, more preferably 3% by mass or less, and even more preferably 1% by mass or less based on 100% by mass of the etching composition of the present invention, since it promotes the dissolution of silicon and has excellent selective solubility of silicon over silicon germanium.

### Glycerol Compound

The etching composition of the present invention preferably has a content of a glycerol compound of 5% by mass or less.

By containing a glycerol compound, a hydrophobic substance that is not miscible with water can become miscible with water. However, the inclusion of the glycerol compound reduces the amount of the components in the composition that contribute to etching, thereby inhibiting the etching of silicon. For this reason, when the composition of the present invention contains a glycerol compound, the selective solubility of silicon over silicon germanium is impaired.

For this reason, the content of the glycerol compound based on 100% by mass of the etching composition of the present invention is preferably 5% by mass or less, more preferably 1% by mass or less, and most preferably contains no glycerol compounds (the content of the glycerol compound is 0% by mass).

However, the glycerol compound does not contain the thiol compound (B) such as thioglycerol and the like.

### Component (C)

It is preferable that the etching composition of the present invention includes water (C) (component (C)), in addition to the component (A) and the component (B).

The content of the component (C) is preferably 60% by mass or more, more preferably 65% by mass or more, and even more preferably 70% by mass or more based on 100% by mass of the etching composition of the present invention, since the composition is easy to produce, promotes the dissolution of silicon, and has excellent selective solubility of silicon over silicon germanium.

When the composition of the present invention contains the component (A1) as the component (A), the content of the component (C) is preferably 94.99% by mass or less, more preferably 89% by mass or less, and even more preferably 84% by mass or less based on 100% by mass of the etching composition of the present invention, from the viewpoints of preventing the dissolution of silicon germanium and providing excellent selective solubility of silicon over silicon germanium.

When the composition of the present invention contains the component (A2) as the component (A), the content of the component (C) is preferably 99.49% by mass or less, more preferably 98% by mass or less, and even more preferably 95% by mass or less based on 100% by mass of the etching composition of the present invention, from the viewpoints of preventing the dissolution of silicon germanium and providing excellent selective solubility of silicon over silicon germanium.

### Other Components

The etching composition of the present invention may contain other components in addition to the above component (A), component (B), and component (C).

Other components include a chelating agent.

When the etching composition of the present invention contains a chelating agent, it exerts an effect of protecting silicon germanium.

Examples of the chelating agent include amine compounds, amino acids, organic acids, and the like. These chelating agents may be used alone or in combination of two or more. Among these chelating agents, amine compounds, amino acids, and organic acids are preferred, and amine compounds are more preferred, in terms of providing excellent selective solubility of silicon over silicon germanium.

Examples of amine compounds include ethylenediamine, 1,3-diaminopropane, 1,4-diaminobutane, ethylenediaminetetraacetic acid, diethylenetriaminepentaacetic acid, triethylenetetraaminehexaacetic acid, diethylenetriaminepentakis (methylphosphonic acid), ethylenediamine-N,N′-bis[2-(2-hydroxyphenyl)acetic acid], N,N′-bis(3-aminopropane)ethylenediamine, N-methyl-1,3-diaminopropane, 2-aminoethanol, N-methyldiethanolamine, 2-amino-2-methyl-1-propanol, and the like. These amine compounds may be used alone or in combination of two or more.

Among these amine compounds, ethylenediamine, 1,3-diaminopropane, 1,4-diaminobutane, ethylenediaminetetraacetic acid, diethylenetriaminepentaacetic acid, triethylenetetraaminehexaacetic acid, diethylenetriaminepentakis (methylphosphonic acid), ethylenediamine-N,N′-bis[2-(2-hydroxyphenyl)acetic acid], N,N′-bis(3-aminopropane)ethylenediamine, N-methyl-1,3-diaminopropane, 2-aminoethanol, N-methyldiethanolamine, and 2-amino-2-methyl-1-propanol are preferred, and ethylenediamine, 1,3-diaminopropane, 1,4-diaminobutane, ethylenediaminetetraacetic acid, diethylenetriaminepentaacetic acid, triethylenetetraaminehexaacetic acid, diethylenetriaminepentakis (methylphosphonic acid), and ethylenediamine-N,N′-bis[2-(2-hydroxyphenyl)acetic acid] are more preferred, in terms of providing excellent selective solubility of silicon over silicon germanium.

Examples of amino acids include glycine, arginine, histidine, (2-dihydroxyethyl) glycine, and the like. These amino acids may be used alone or in combination of two or more.

Among these amino acids, glycine, arginine, histidine, (2-dihydroxyethyl)glycine are preferred, and (2-dihydroxyethyl)glycine is more preferred, in terms of providing excellent selective solubility of silicon over silicon germanium.

Examples of organic acids include oxalic acid, citric acid, tartaric acid, malic acid, 2-phosphonobutane-1,2,4-tricarboxylic acid, and the like. These organic acids may be used alone or in combination of two or more.

Among these organic acids, oxalic acid, citric acid, tartaric acid, malic acid, and 2-phosphonobutane-1,2,4-tricarboxylic acid are preferred, and citric acid and 2-phosphonobutane-1,2,4-tricarboxylic acid are more preferred, in terms of providing excellent selective solubility of silicon over silicon germanium.

When the etching composition of the present invention contains the chelating agent, the content of the chelating agent is preferably 0.001% by mass or more, more preferably 0.005% by mass or more, and even more preferably 0.01% by mass or more based on 100% by mass of the etching composition of the present invention, in terms of providing excellent selective solubility of silicon over silicon germanium.

The content of the chelating agent is preferably 25% by mass or less, more preferably 10% by mass or less, and even more preferably 6% by mass or less based on 100% by mass of the etching composition of the present invention, in terms of providing excellent selective solubility of silicon over silicon germanium.

The etching composition of the present invention may contain a water-miscible solvent. By containing a water-miscible solvent, hydrophobic substances that are not miscible with water can be made miscible with water. On the other hand, containing a water-miscible solvent reduces the amount of the components in the composition that contribute to etching, thereby inhibiting etching of silicon. For this reason, it is preferable that the etching composition of the present invention does not contain a water-miscible solvent.

The water-miscible solvent may be any solvent that has excellent solubility in water, and a solvent having a solubility parameter (SP value) of 7.0 or more is preferable, and a solvent having a solubility parameter (SP value) of 9.0 or more is more preferable.

Examples of the water-miscible solvent include polar protic solvents such as isopropanol, ethylene glycol, propylene glycol, methanol, ethanol, propanol, butanol, glycerol, 2-(2-aminoethoxyethanol), and the like; polar aprotic solvents such as acetone, dimethyl sulfoxide, N,N-dimethylformamide, N-methylpyrrolidone, acetonitrile, and the like; and nonpolar solvents such as hexane, benzene, toluene, diethyl ether, and the like. These water-miscible solvents may be used alone or in combination of two or more.

When the etching composition of the present invention contains these water-miscible solvents, the content of the water-miscible solvent is preferably 5% by mass or less, and more preferably 1% by mass or less based on 100% by mass of the etching composition of the present invention, and most preferably contains no water-miscible solvents.

Examples of the other components that may be contained in the etching composition of the present invention include surfactants such as anionic surfactants, nonionic surfactants, cationic surfactants, and the like; water-soluble polymers such as polyvinyl alcohol, polyethylene glycol, polypropylene glycol, polyethyleneimine, polypropyleneimine, polyacrylic acid, and the like; oxidizing agents such as hydrogen peroxide, perchloric acid, periodic acid, and the like; and reducing agents such as ascorbic acid, gallic acid, pyrogallol, pyrocatechol, resorcinol, hydroquinone, 8-hydroxyquinoline, and the like. These other components may be used alone or in combination of two or more.

### Mass Ratio of Each Component

The mass ratio of the component (B) to the component (A) in the etching composition of the present invention (mass of the component (B)/mass of the component (A)) is preferably 0.001 to 2, and more preferably 0.003 to 1.5, in terms of providing excellent selective solubility of silicon over silicon germanium.

When the composition of the present invention contains the component (A1) as the component (A), the mass ratio of the component (B) to the component (A1) in the etching composition of the present invention (mass of the component (B)/mass of the component (A1)) is preferably 0.001 to 0.1, and more preferably 0.002 to 0.05, in terms of providing excellent selective solubility of silicon over silicon germanium.

When the composition of the present invention contains the component (A2) as the component (A), the mass ratio of the component (B) to the component (A2) in the etching composition of the present invention (mass of the component (B)/mass of the component (A2)) is preferably 0.001 to 2, and more preferably 0.1 to 1.5, in terms of providing excellent selective solubility of silicon over silicon germanium.

When the etching composition of the present invention contains the component (C), the mass ratio of the component (A) to the component (C) (mass of the component (A)/mass of the component (C)) is preferably 0.01 to 0.55, and more preferably 0.03 to 0.45, in terms of providing excellent selective solubility of silicon over silicon germanium.

When the composition of the present invention containing the component (A1) as the component (A) contains the component (C), the mass ratio of the component (A1) to the component (C) (mass of the component (A1)/mass of the component (C)) is preferably 0.06 to 0.6, and more preferably 0.08 to 0.5, in terms of providing excellent selective solubility of silicon over silicon germanium.

When the composition of the present invention containing the component (A2) as the component (A) contains the component (C), the mass ratio of the component (A2) to the component (C) (mass of the component (A2)/mass of the component (C)) is preferably 0.001 to 0.6, and more preferably 0.005 to 0.1, in terms of providing excellent selective solubility of silicon over silicon germanium.

When the etching composition of the present invention contains the component (C), the mass ratio of the component (B) to the component (C) (mass of the component (B)/mass of the component (C)) is preferably 0.0005 to 0.05, and more preferably 0.001 to 0.02, in terms of providing excellent selective solubility of silicon over silicon germanium.

### Method for Producing the Composition

Methods for producing the composition of the present invention are not particularly limited. The composition can be produced by mixing the component (A) and the component (B) with the component (C) and other components, as necessary.

The order of the mixing is not particularly limited. All the components may be mixed together at one time, or some of the components are first mixed together, and subsequently, the other components may be mixed therewith.

### Physical Properties of the Composition

The pH of the composition of the present invention is preferably 8 to 14, more preferably 9 to 14, and even more preferably 10 to 14, in terms of providing an excellent etching rate of silicon.

The etching rate ERsi of silicon of the composition of the present invention in a structure, in which silicon germanium having a film thickness of 10 nm and silicon having a film thickness of 10 nm are stacked, is preferably 5 nm/min or more, and more preferably 10 nm/min or more, in terms of providing excellent selective solubility of silicon over silicon germanium.

The etching rate ER_{SiGe} of silicon germanium of the composition of the present invention in a structure, in which silicon germanium having a film thickness of 10 nm and silicon having a film thickness of 10 nm are stacked, is preferably 4 nm/min or less, and more preferably 2 nm/min or less, in terms of providing excellent selective solubility of silicon over silicon germanium.

The etching rate ratio (ER_{Si}/ER_{SiGe}) of the etching composition of the present invention, which corresponds to the dissolution selectivity ratio of silicon germanium to silicon in a structure in which silicon germanium having a film thickness of 10 nm and single crystal silicon having a film thickness of 10 nm are stacked, is preferably 3 or more, more preferably 5 or more, and even more preferably 10 or more, in terms of providing excellent selective solubility of silicon over silicon germanium.

The etching rate ER_{Si}, the etching rate ER_{SiGe}, and the dissolution selectivity ratio (ER_{Si}/ER_{SiGe}) are measured and calculated by the methods described in the Examples section below.

### Object to be Etched by the Composition

The etching composition of the present invention promotes the dissolution of silicon while suppressing the dissolution of silicon germanium, and has excellent selective solubility of silicon over silicon germanium, so it is suitable for an etching liquid, more suitable for an etching liquid that dissolves silicon, and particularly suitable for an etching liquid that suppresses the dissolution of silicon germanium and dissolves silicon.

Therefore, the etching composition of the present invention is suitable for structures containing silicon as etching targets, more suitable for structures containing silicon and silicon germanium, and particularly suitable for structures in which silicon and silicon germanium are alternately layered, which are necessary for the formation of GAA FETs.

Structures containing silicon, structures containing silicon and silicon germanium, and structures in which silicon and silicon germanium are alternately layered, which are necessary for the formation of GAA FETs, are used in semiconductor devices.

The silicon that is an object to be etched is preferably single-crystal silicon, since single-crystal silicon germanium has excellent characteristics as a gate-all-around transistor, and single-crystal silicon germanium is less likely to have defects when epitaxially grown on single-crystal silicon germanium.

A content of the silicon in the silicon germanium that is an object to be etched is preferably 10% by mass or more, and more preferably 20% by mass or more based on 100% by mass of the silicon germanium, because such a content is suitable for the etching performed with the etching composition of the present invention.

The content of the silicon in the silicon germanium that is an object to be etched is preferably 95% by mass or less, and more preferably 85% by mass or less based on 100% by mass of the silicon germanium, because such a content is suitable for the etching performed with the etching composition of the present invention.

A content of the germanium in the silicon germanium that is an object to be etched is preferably 5% by mass or more, and more preferably 15% by mass or more based on 100% by mass of the silicon germanium, because such a content is suitable for the etching performed with the etching composition of the present invention.

The content of the germanium in the silicon germanium that is an object to be etched is preferably 90% by mass or less, and more preferably 80% by mass or less based on 100% by mass of the silicon germanium, because such a content is suitable for the etching performed with the etching composition of the present invention.

An alloy film of the silicon germanium may be produced by performing film formation with a known method. The alloy film may be produced by performing film deposition with a crystal growth method, which is preferable because, in such a case, an enhanced mobility of electrons and holes is exhibited after the formation of transistors.

The structure containing silicon and silicon germanium and the structure in which silicon and silicon germanium are alternately layered may have one or more areas in which silicon oxide, silicon nitride, silicon carbonitride, and/or the like are exposed.

### Etching Method

An etching method of the present invention is a method for etching a structure that contains silicon and silicon germanium by using an etching composition of the present invention.

As described above, the silicon that is an object to be etched is preferably single-crystal silicon, since single-crystal silicon germanium has excellent characteristics as a gate-all-around transistor, and single-crystal silicon germanium is less likely to have defects when epitaxially grown on single-crystal silicon germanium.

The process of the etching may be a known process, which may be, for example, a batch process, a single-wafer process, or the like.

It is preferable that a temperature during the etching be higher than or equal to 15° C., because, in this case, the etch rate can be improved. The temperature is more preferably higher than or equal to 20° C.

From the standpoint of a reduction in damage to a substrate and the stability of etching, it is preferable that the temperature during the etching be lower than or equal to 100° C. More preferably, the temperature is lower than or equal to 80° C.

As referred to herein, the temperature during the etching is a temperature of the etching composition during the etching.

### Uses

The etching composition of the present invention promotes the dissolution of silicon while suppressing the dissolution of silicon germanium, and has excellent selective solubility of silicon over silicon germanium, so it is suitable for an etching liquid, more suitable for an etching liquid that dissolves silicon, and particularly suitable for an etching liquid that suppresses the dissolution of silicon germanium and dissolves silicon.

Therefore, the etching compositions of the present invention and the etching method of the present invention can be suitably used in the manufacture of semiconductor devices that involves a step of etching a structure that contains silicon and silicon germanium. The etching compositions and the etching method promote dissolution of silicon while inhibiting dissolution of silicon germanium and, therefore, have excellent ability to selectively dissolve silicon over silicon germanium. Accordingly, the etching compositions of the present invention and the etching method of the present invention can be particularly suitably used in the manufacture of GAA FETs that involves a step of etching a structure containing silicon and silicon germanium. It is particularly suitable for a structure in which silicon and silicon germanium are alternately layered, which is necessary for the formation of GAA FETS.

### EXAMPLES

The present invention will now be described in more detail with reference to examples. The present invention is not limited to the description of the examples below as long as the scope thereof remains unchanged.

### Raw Materials

In Examples and Comparative Examples, described below, the following raw materials were used for the production of compositions.
Component (A1-1): Tetrabutylammonium hydroxide
Component (A1-2): Tetramethylammonium hydroxide
Component (A1-3): Tetraethylammonium hydroxide
Component (A2-1): Potassium hydroxide
Component (B-1): 11-mercaptoundecanoic acid
Component (B-2): 8-mercaptooctanoic acid
Component (B-3): 16-mercaptohexadecanoic acid
Component (B-4): 4-hydroxybenzenethiol
Component (B-5): 1-dodecanethiol
Component (B′-1): 1-dodecanol
Component (B′-2): 1-dodecane
Component (X-1): Glycerol

### Etch Rate for Single Crystal Silicon

A substrate was immersed in a 0.5% by mass aqueous hydrofluoric acid solution for 60 seconds. The substrate included a structure in which silicon germanium having a film thickness of 10 nm and single crystal silicon having a film thickness of 10 nm (width of the single crystal silicon layer before immersion=10 nm) were layered. Subsequently, the substrate was rinsed with ultrapure water, and subsequently, the substrate was immersed in the etching compositions obtained in the Examples and the Comparative Examples, at 50° C. for 5 to 15 minutes. After the immersion, a cross section of the substrate was examined with an electron microscope to measure the width [nm] of the single crystal silicon layer, and the etch rate for single crystal silicon ER_{Si} [nm/minute] was calculated according to the equation (1) below.

$${ER}_{S i} [ nm / min ] = ( Width of silicon layer before immersion [ nm ] - Width of silicon layer after immersion [ nm ] ) / ( Immersion time [ min ] ) / 2 \qquad ( 1 )$$

### Etch Rate for Silicon Germanium

A substrate was immersed in a 0.5% by mass aqueous hydrofluoric acid solution for 60 seconds. The substrate included a structure in which silicon germanium having a film thickness of 10 nm (width of the silicon germanium layer before immersion=10 nm) and single crystal silicon having a film thickness of 10 nm were layered. Subsequently, the substrate was rinsed with ultrapure water, and subsequently, the substrate was immersed in the etching compositions obtained in the Examples and the Comparative Examples, at 50° C. for 5 to 15 minutes. After the immersion, a cross section of the substrate was examined with an electron microscope to measure the width [nm] of the silicon germanium layer, and the etch rate for the silicon germanium layer ER_{SiGe} [nm/minute] was calculated according to the equation (2) below.

$${ER}_{SiGe} [ nm / min ] = ( Width of silicon germanium layer before immersion [ nm ] - Width of silicon germanium layer after immersion [ nm ] ) \text{} / ( Immersion time [ min ] ) / 2 \qquad ( 2 )$$

### Dissolution Selectivity for Single Crystal Silicon and Silicon Germanium

The dissolution selectivity for silicon germanium and single crystal silicon was calculated according to the equation (3) below.

$$Dissolution selectivity = {ER}_{S i} [ nm / min ] / {ER}_{SiGe} [ nm / min ]$$

(3)

### Example 1

The composition was prepared by mixing components together such that the component (A1-1) was present in an amount of 26.0% by mass, and the component (B-1) was present in an amount of 0.1% by mass, with the balance being water, based on 100% by mass of the composition.

The results of evaluation of the prepared composition are shown in Table 1.

### Examples 2, 10, and Comparative Examples 1, 7, 8

Each composition was prepared by performing the same operation as in Example 1, except that the type and/or content of each component in the composition employed was changed as shown in Table 1.

### Examples 3 to 9, 11, and Comparative Examples 2 to 5

Each composition was prepared by performing the same operation as in Example 1, except that the type and/or content of each component in the composition employed was changed as shown in Table 1, and nitrogen gas was bubbled for 5 minutes. In addition, the composition was evaluated by the same procedure as in Example 1, except that bubbling was also performed when immersing the substrate.

### Example 12

The composition was prepared by mixing components together such that the component (A2-1) was present in an amount of 5.6% by mass, and the component (B-1) was present in an amount of 1.0% by mass, with the balance being water, based on 100% by mass of the composition, and bubbling with nitrogen gas for 5 minutes. In addition, the composition was evaluated by the same procedure as in Example 1, except that bubbling was also performed when immersing the substrate.

### Examples 13 to 14, and Comparative Example 6

Each composition was prepared by performing the same operation as in Example 12, except that the type and/or content of each component in the composition employed was changed as shown in Table 1.

The results of evaluation of the prepared compositions are shown in Table 1.

TABLE 1

| | | Component (A) | | Component (B) | | Other component | | | | |
|---|---|---|---|---|---|---|---|---|---|---|
| | | | Content | | Content | | Content | ER_{Si} | ER_{SiGe} | Dissolution |
| | | Type | [% by mass] | Type | [% by mass] | Type | [% by mass] | [nm/min] | [nm/min] | Selectivity |
| Example | 1 | (A1-1) | 26 | (B-1) | 0.1 | — | — | 10.4 | 1.8 | 5.7 |
| | 2 | (A1-1) | 26 | (B-1) | 0.1 | (X-1) | 20 | 9.3 | 2.3 | 4.1 |
| | 3 | (A1-1) | 26 | (B-1) | 0.05 | — | — | 5.3 | 0.8 | 6.4 |
| | 4 | (A1-1) | 26 | (B-1) | 0.1 | — | — | 8.5 | 1.5 | 5.6 |
| | 5 | (A1-1) | 26 | (B-1) | 1 | — | — | 4.3 | 0.6 | 6.8 |
| | 6 | (A1-1) | 26 | (B-2) | 0.1 | — | — | 4.1 | 0.5 | 8.0 |
| | 7 | (A1-1) | 26 | (B-3) | 0.1 | — | — | 4.0 | 0.5 | 7.7 |
| | 8 | (A1-1) | 26 | (B-4) | 0.1 | — | — | 2.4 | 0.5 | 4.6 |
| | 9 | (A1-1) | 26 | (B-5) | 1 | — | — | 2.4 | 0.6 | 4.3 |
| | 10 | (A1-2) | 9.1 | (B-1) | 1 | — | — | 3.2 | 0.5 | 6.8 |
| | 11 | (A1-3) | 15 | (B-1) | 1 | — | — | 4.1 | 0.5 | 7.8 |
| | 12 | (A2-1) | 5.6 | (B-1) | 1 | — | — | 3.2 | 0.5 | 6.0 |
| | 13 | (A2-1) | 0.56 | (B-1) | 0.4 | — | — | 1.5 | 0.2 | 9.8 |
| | 14 | (A2-1) | 0.56 | (B-1) | 0.7 | — | — | 1.5 | 0.1 | 30.3 |
| Comparative | 1 | (A1-1) | 26 | — | — | — | — | 8.1 | 5.4 | 1.5 |
| Example | 2 | (A1-1) | 26 | (B1′-1) | 1 | — | — | 4.6 | 2.4 | 2.0 |
| | 3 | (A1-1) | 26 | (B1′-2) | 1 | — | — | 5.3 | 3.5 | 1.5 |
| | 4 | (A1-2) | 9.1 | — | — | — | — | 11.3 | 9.4 | 1.2 |
| | 5 | (A1-3) | 15 | — | — | — | — | 13.6 | 13.7 | 1.0 |
| | 6 | (A2-1) | 5.6 | — | — | — | — | 12.2 | 8.4 | 1.5 |
| | 7 | — | — | (B-1) | 0.1 | — | — | 0 | 0 | — |
| | | — | — | (B-1) | 1 | — | — | 0 | 0 | — |

As can be seen from Table 1, the compositions of Examples 1 to 14, which contain the component (A) and the component (B), promote dissolution of silicon while inhibiting dissolution of silicon germanium and, therefore, have excellent ability to selectively dissolve silicon over silicon germanium.

On the other hand, the compositions of Comparative Examples 1 to 6, which do not contain the component (B), are inferior in ability to selectively dissolve silicon over silicon germanium.

In Comparative Examples 7 and 8, which do not contain the component (A), neither silicon nor silicon germanium can be dissolved.

### INDUSTRIAL APPLICABILITY

The etching compositions of the present invention and the etching method of the present invention, which uses any of the compositions, promote dissolution of silicon while inhibiting dissolution of silicon germanium and, therefore, have excellent ability to selectively dissolve silicon over silicon germanium. Accordingly, the etching composition of the present invention and the etching method of the present invention using this etching composition are suitable for structures containing silicon as the object to be etched. For example, the etching compositions of the present invention and the etching method of the present invention can be suitably used in the manufacture of semiconductor devices and, in particular, can be suitably used in the manufacture of GAA FETs.

Although the present invention has been described in detail with reference to particular embodiments, it will be apparent to those skilled in the art that various changes can be made without departing from the spirit and the scope of the present invention.

The present application is based on Japanese Patent Application No. 2023-019284 filed on Feb. 10, 2023 and Japanese Patent Application No. 2023-084973 filed on May 23, 2023, which are herein incorporated in their entirety by reference.

1. An etching composition comprising an alkaline compound and a thiol compound, wherein the etching composition is configured to dissolve silicon.

2. The etching composition according to claim 1, wherein the silicon is single crystal silicon.

3. The etching composition according to claim 1, wherein the alkaline compound comprises a quaternary ammonium compound.

4. The etching composition according to claim 3, wherein the quaternary ammonium compound comprises a quaternary alkylammonium compound having a total of 8 or more carbon atoms in the alkyl groups.

5. The etching composition according to claim 3, wherein the quaternary ammonium compound comprises a semiclathrate hydrate-forming compound.

6. The etching composition according to claim 1, wherein the alkaline compound comprises an inorganic alkaline compound.

7. The etching composition according to claim 6, wherein the inorganic alkaline compound comprises a metal hydroxide.

8. The etching composition according to claim 7, wherein the inorganic alkali compound comprises potassium hydroxide.

9. The etching composition according to claim 1, wherein the thiol compound comprises a compound having a hydrocarbon group and a thiol group.

10. The etching composition according to claim 1, wherein the thiol compound comprises at least one compound selected from the group consisting of thioglycerol, thioglycolic acid, ethanolamine thioglycolate, 8-mercaptooctanoic acid, 1-octanethiol, 1-undecanethiol, 1-dodecanethiol, 11-mercapto-1-undecanol, 11-mercaptoundecanoic acid, 16-mercaptohexadecanoic acid, 4,4′-dithiodibutyric acid, bis(2-hydroxyethyl) disulfide, and didodecane disulfide.

11. The etching composition according to claim 1, further comprising water.

12. The etching composition according to claim 11, wherein a content of water is 60% by mass or more based on 100% by mass of the etching composition.

13. The etching composition according to claim 1, wherein a content of the alkaline compound (A) is 0.1% by mass or more and 39.99% by mass or less based on 100% by mass of the etching composition.

14. The etching composition according to claim 1, wherein a content of the thiol compound (B) is 0.01% by mass or more and 5% by mass or less based on 100% by mass of the composition.

15. The etching composition according to claim 1, wherein a ratio of the mass of the thiol compound (B) to the mass of the alkaline compound (A) is 0.001 to 2.

16. The etching composition according to claim 1, wherein a content of a glycerol compound is 5% by mass or less based on 100% by mass of the composition.

17. The etching composition according to claim 1, wherein the composition has a ratio ER_{Si}/ER_{SiGe} of 3 or more, wherein ER_{Si} is an etching rate for single crystal silicon and ER_{SiGe} is an etching rate for silicon germanium in a structure, in which silicon germanium having a film thickness of 10 nm and single crystal silicon having a film thickness of 10 nm are stacked.

18. A method comprising etching silicon by using the etching composition according to claim 1.

19. The method according to claim 18, wherein the silicon is single crystal silicon.

20. A method for manufacturing a semiconductor device comprising etching silicon by using the etching composition according to claim 1.

21. The method for manufacturing a semiconductor device according to claim 20, wherein the silicon is single crystal silicon.

22. A method for manufacturing a gate-all-around transistor comprising etching silicon by using the etching composition according to claim 1.

23. The method for manufacturing a gate-all-around transistor according to claim 22, wherein the silicon is single crystal silicon.
